(19) United States
(12) Patent Application Publication
(10) Pub. No.: US 2004/0124509 A1
(43) Pub. Date: Jul. 1, 2004

(54) Method and structure for vertically-stacked device contact

(76) Inventors: Sarah E. Kim, Portland, OR (US); R. Scott List, Beaverton, OR (US)

Correspondence Address: Michael A. Bernadicou, Blakely Sokoloff Taylor & Zafman LLP, 12400 Wilshire Boulevard, seventh Floor, Los Angeles, CA, 90025, US

(21) Appl. No.: 10/334,196

(22) Filed: Dec. 28, 2002

(51) Int. Cl. H01L 23/02; H01L 21/44

(52) U.S. Cl. 257/678; 438/597; 438/598

(57) ABSTRACT

Method and structure for vertically stacking microelectronic devices are disclosed. Subsequent to appropriate deposition, patterning, trenching, and passivation subprocesses, a conductive layer is formed wherein one end comprises an external contact portion for C4 interfacing, and another end establishes electrical contact with an internal contact at the bonding interface between the two interfaced devices. The conductive layer may be formed using electroplating, and may be formed in a single electroplating treatment, to form a continuous structure from via portion to external contact portion.

### BACKGROUND OF THE INVENTION

Integrated circuits (ICs) form the basis for many electronic systems. Essentially, an integrated circuit includes a vast number of transistors and other circuit elements that are formed on a single semiconductor wafer or chip and are interconnected to implement a desired function. The complexity of these integrated circuits requires the use of an ever increasing number of linked transistors and other circuit elements.

Many modern electronic systems are created through the use of a variety of different integrated circuits; each integrated circuit performing one or more specific functions. For example, computer systems include at least one microprocessor and a number of memory chips. Conventionally, each of these integrated circuits is formed on a separate chip, packaged independently and interconnected on, for example, a printed circuit board (PCB).

As integrated circuit technology progresses, there is a growing desire for a “system on a chip” in which the functionality of all of the IC devices of the system are packaged together without a conventional PCB. Ideally, a computing system should be fabricated with all the necessary IC devices on a single chip. In practice, however, it is very difficult to implement a truly high-performance “system on a chip” because of vastly different fabrication processes and different manufacturing yields for the logic and memory circuits.

As a compromise, various “system modules” have been introduced that electrically connect and package integrated circuit devices which are fabricated on the same or on different semiconductor wafers. Initially, system modules have been created by simply stacking two chips, e.g., a logic and memory chip, one on top of the other in an arrangement commonly referred to as chip-on-chip structure. Subsequently, multi-chip module (MCM) technology has been utilized to stack a number of chips on a common substrate to reduce the overall size and weight of the package, which directly translates into reduced system size.

Existing multi-chip module technology is known to provide performance enhancements over single chip or chip-on-chip (COC) packaging approaches. For example, when several semiconductor chips are mounted and interconnected on a common substrate through very high density interconnects, higher silicon packaging density and shorter chip-to-chip interconnections can be achieved. In addition, low dielectric constant materials and higher wiring density can also be obtained which lead to the increased system speed and reliability, and the reduced weight, volume, power consumption and heat to be dissipated for the same level of performance. However, MCM approaches still suffer from additional problems, such as bulky package, wire length and wire bonding that gives rise to stray inductances that interfere with the operation of the system module.

An advanced three-dimensional (3D) wafer-to-wafer vertical stack technology has been recently proposed by researchers to realize the ideal high-performance “system on a chip” as described in “Face To Face Wafer Bonding For 3D Chip Stack Fabrication To Shorten Wire Lengths” by J. F. McDonald et al., Rensselaer Polytechnic Institute (RPI) presented on Jun. 27-29, 2000 VMIC Conference, and “Copper Wafer Bonding” by A. Fan et al., Massachusetts Institute of Technology (MIT), Electrochemical and Solid-State Letters, 2 (10) 534-536 (1999). In contrast to the existing multi-chip module technology which seeks to stack multiple chips on a common substrate, 3-D wafer-to-wafer vertical stack technology seeks to achieve the long-awaited goal of vertically stacking many layers of active IC devices such as processors, programmable devices and memory devices inside a single chip to shorten average wire lengths, thereby reducing interconnect RC delay and increasing system performance. One major challenge of 3-D wafer-to-wafer vertical stack integration is the bonding between wafers and between die in a single chip. In the RPI publication, polymer glue is used to bond the vertically stacked wafers. In the MIT publication, copper (Cu) is used to bond the vertically stacked wafers; however, a handle (carrier wafer) is required to transport thinly stacked wafers and a polymer glue is also used to affix the handle on the top wafer during the vertically stacked wafer processing.

In U.S. patent application Ser. No. 10/077,967, a technique for vertically stacking multiple wafers supporting different active IC devices is disclosed, wherein damascene process technology is utilized to provide high-density signal access between silicon layers. This previously described damascene flow is complex and expensive, and a more streamlined solution is needed for certain scenarios where a more simplified solution may be applied.

### BRIEF DESCRIPTION OF THE DRAWINGS

The present invention is illustrated by way of example and is not limited in the figures of the accompanying drawings, in which like references indicate similar elements. Features shown in the drawings are not intended to be drawn to scale, nor are they intended to be shown in precise positional relationship;

FIG. 1 depicts a cross sectional view of one embodiment of the present invention having a simplified contact for two vertically stacked wafer-based devices.

FIGS. 2A-2M depict cross sectional views of various aspects of one embodiment of the present invention wherein a simplified process is used to form a contact for vertically stacked wafer-based devices;

FIG. 3 depicts a flowchart of various aspects of one embodiment of the present invention wherein a simplified process is used to form a contact for vertically stacked wafer-based devices.

### DETAILED DESCRIPTION

In the following detailed description of embodiments of the invention, reference is made to the accompanying drawings in which like references indicate similar elements. The illustrative embodiments described herein are disclosed in sufficient detail to enable those skilled in the art to practice the invention. The following detailed description is therefore not to be taken in a limiting sense, and the scope of the invention is defined only by the appended claims. Further, the present invention is applicable for use with many types of wafers and integrated circuit (IC) devices, including, for example, MOS transistors, CMOS devices, MOSFETs, and memory and communication devices such as smart card, cellular phone, electronic tag, and gaming devices. For the sake of simplicity, description herein is focused mainly upon exemplary use a three-dimensional (3-D) wafer-to-wafer vertical stack, although the scope of the present invention is not limited thereto.

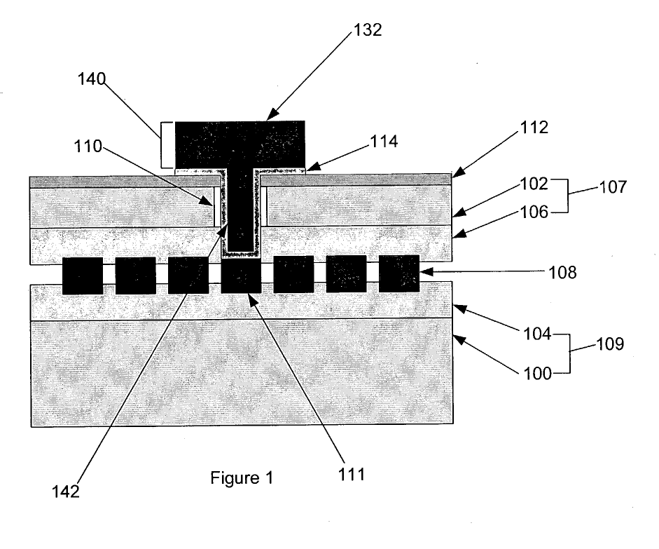

Referring to FIG. 1, a microelectronic structure is shown in cross-sectional view having a first, or “bottom”, substrate layer (109) comprising a bulk substrate layer (100) and an active layer (104). The depicted structure also includes a second, or “top”, substrate layer (107) which also comprises a bulk substrate layer (102) and an active layer (106). The active layers (104, 106) are electrically connected with each other by a series of interfaced conductive lines (108), which preferably comprise pairs of interfaced conductive lines, one of each pair of interfaced conductive lines being coupled to the bottom active layer (104), and the other of each pair being coupled to the top active layer (106). In other words, the depicted series of conductive lines (108) preferably comprises a series of paired conductive lines positioned into immediate contact with one another to provide electrical contact between active areas (104, 106). As shown in FIG. 1, the interior contacts (108) are coupled between the two active layers (104, 106). The manufacture of substrate layers having conductive lines coupled thereto is typically handled separately using conventional techniques as would be apparent to one skilled in the art, subsequent to which the substrates (107, 109) may be oriented and interfaced as shown. Also depicted in FIG. 1 is a conductive layer (132) having an external contact portion (140) and a via portion (142) to provide contact between one of the conductive lines (111) and the external contact portion (140) for purposes of interfacing with the relatively remotely positioned conductive line (111), which also may be referred to as an “internal contact”. The external contact portion (140) is positioned and dimensioned to function as a “controlled collapse chip connection”, or “C4”, contact point for convenient and accessible electrical contact with the internal contact (111), the internal contact (111) being electrically connected to both active areas (104, 106) through the interfacing of the series of conductive lines (108). Also depicted in FIG. 1 are a dielectric plug (110), an etch stop dielectric layer (112), and a barrier layer (114), each of which isolates the conductive layer (132) from the substrate (107) component layers (102, 106) and internal contact (111), as further described below.

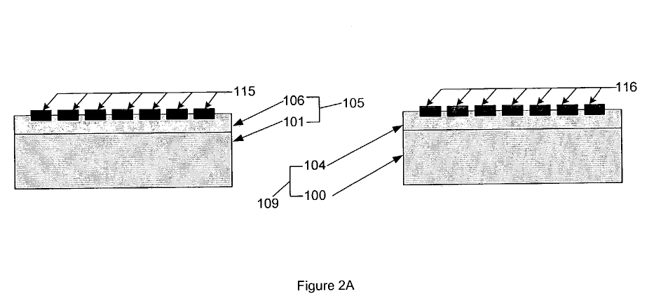

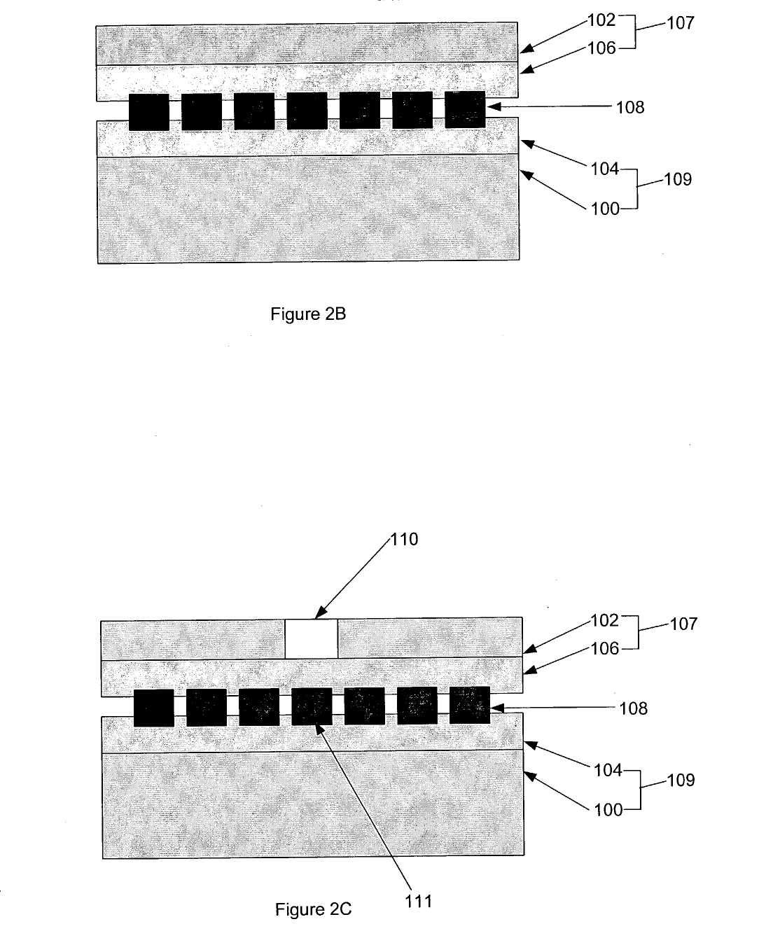

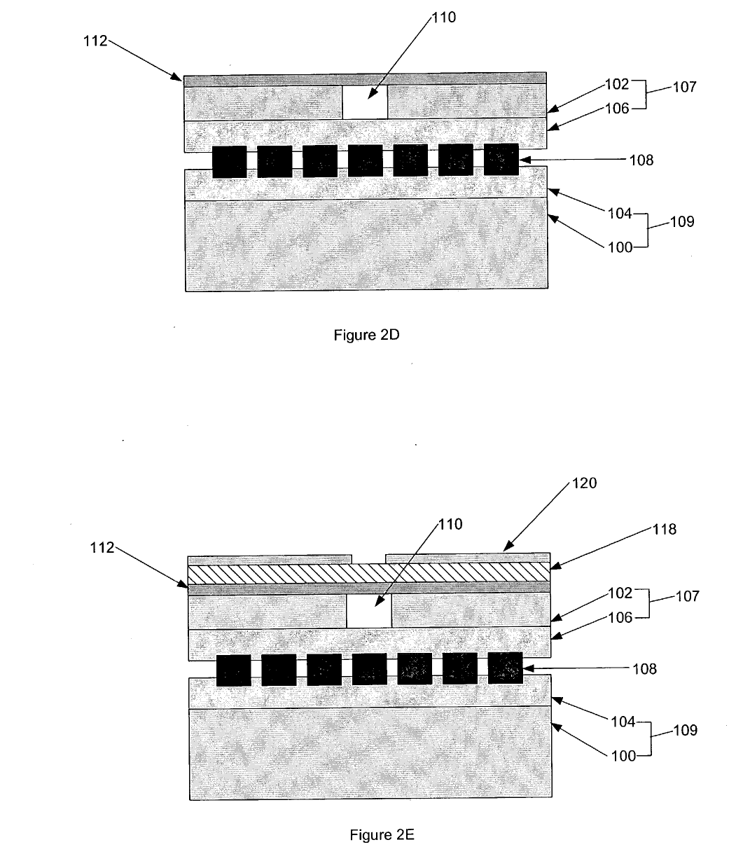

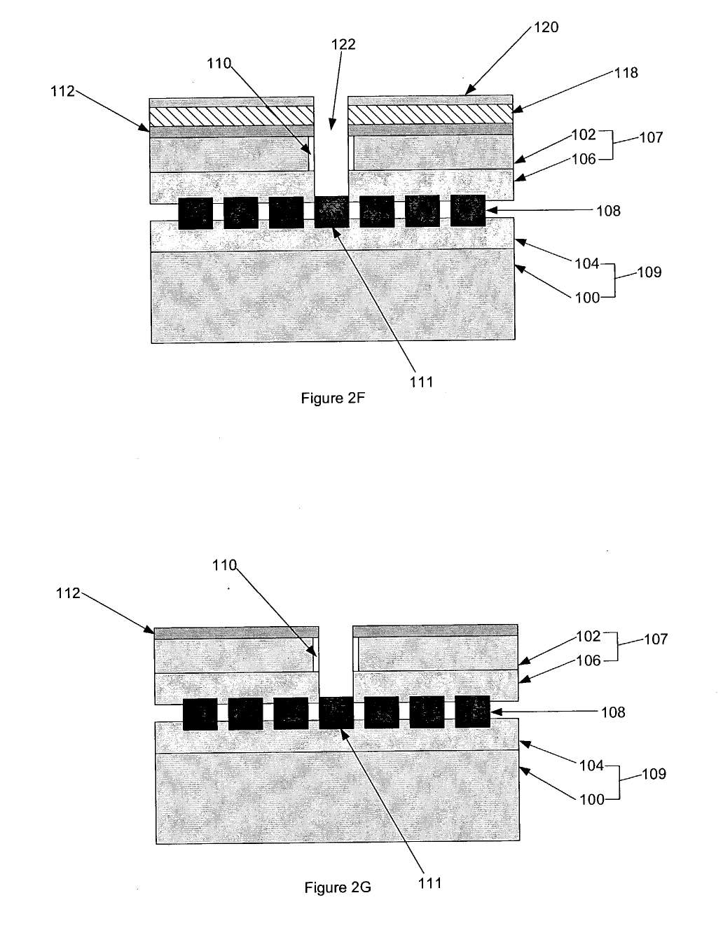

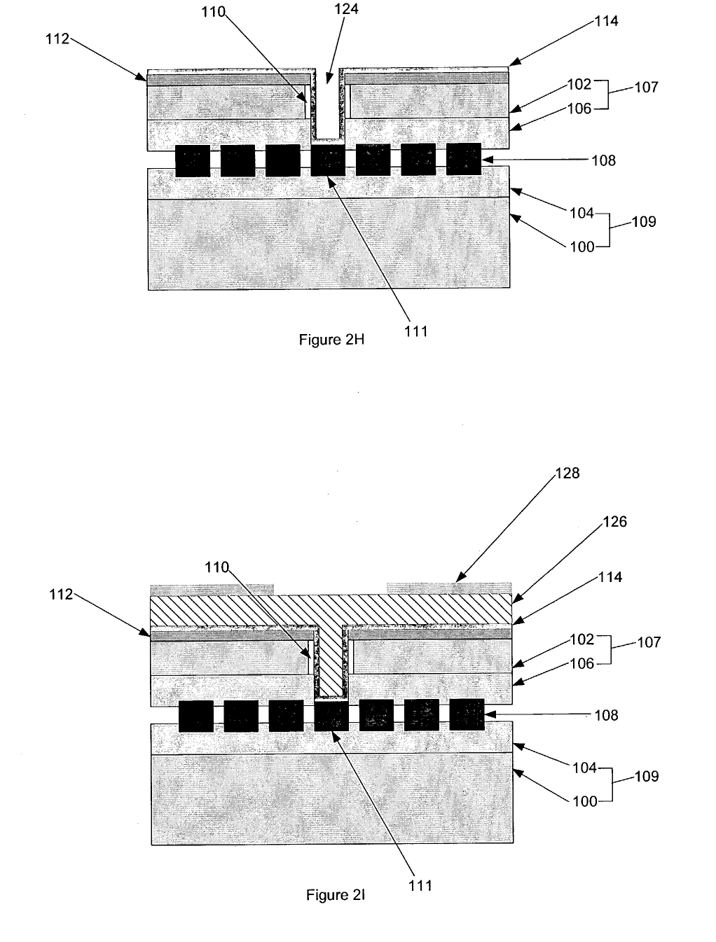

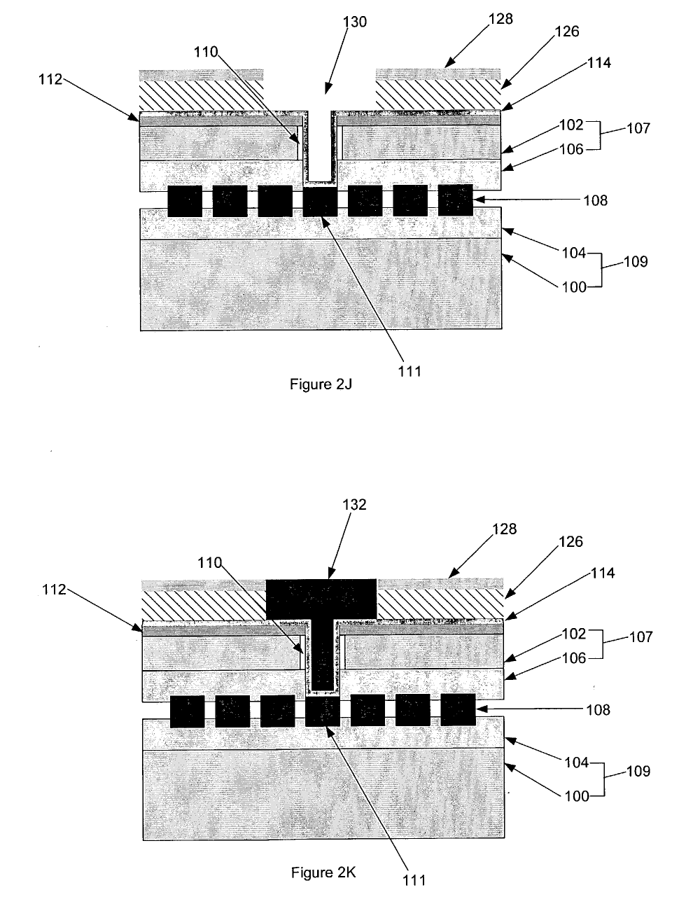

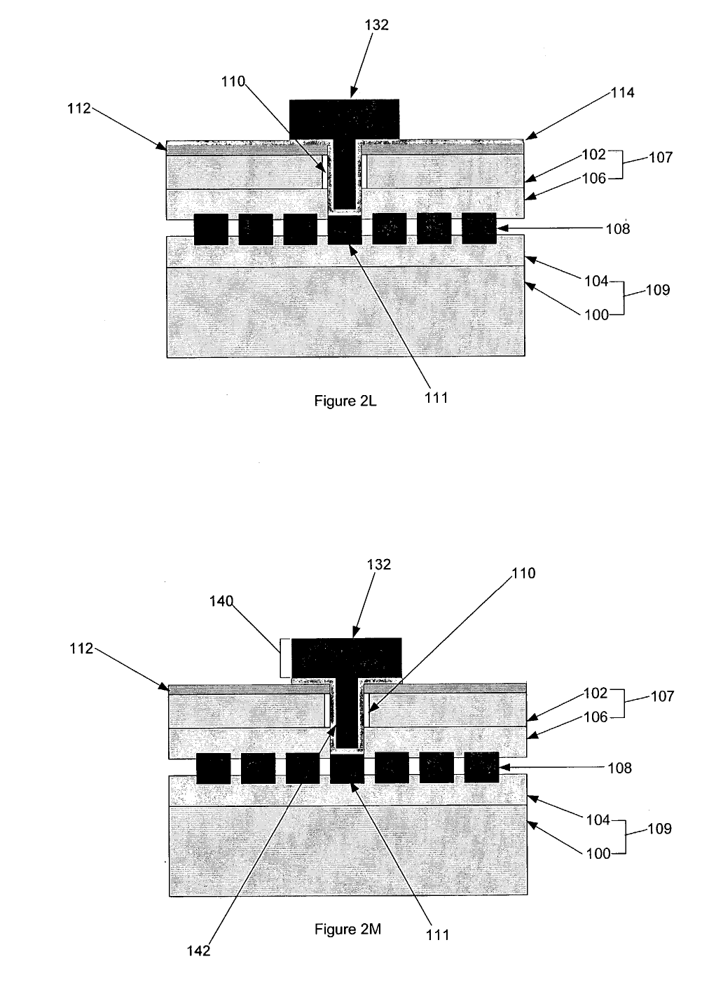

Referring to FIG. 2A, two substrate layers are depicted (105, 109), each of which comprises a bulk substrate layer (101, 100), an active layer (106, 104), and a series of conductive lines (115, 116). The bulk (101, 100) and active (106, 104) layers preferably comprise bulk and doped silicon, respectively, but may comprise many other substrate materials used in microelectronic devices, such as silicon germanium. In other embodiments (not shown), each of the substrate layers (105, 109) may comprise any surface generated when making an integrated circuit, upon which a conductive layer may be formed. The substrates (105, 109) thus may comprise, for example, active and passive devices that are formed on a silicon wafer, such as transistors, capacitors, resistors, diffused junctions, gate electrodes, local interconnects, etcetera. The substrates (105, 109) may also comprise insulating materials or layers (e.g., silicon dioxide, either undoped or doped with phosphorus or boron and phosphorus; silicon nitride; silicon oxynitride; or a polymer) that separate active and passive devices from the conductive layer or layers that are formed adjacent them, and may comprise other previously formed conductive layers.

Each of the depicted series of conductive lines (115, 116) is shown protruding slightly from the associated active layer (106, 104). Such protrusion may be achieved using chemical mechanical polishing techniques, such as those described in the U.S. patent application for the invention entitled, “Differential Planarization”, assigned to the same assignee as the present invention and filed simultaneously. The two series of conductive lines (115, 116) of the depicted embodiment may comprise metals such as copper, aluminum, tungsten, titanium, tin, indium, gold, nickel, palladium, and alloys thereof, formed using known techniques such as electroplating or chemical or physical vapor deposition. Alternatively, the conductive lines (115, 116) may be made from doped polysilicon or a silicide, e.g., a silicide comprising tungsten, titanium, nickel, or cobalt, using known techniques.

Referring to FIG. 2B, the two series of conductive lines depicted in FIG. 2A (115, 116) are shown interfaced to form a series of interfaced conductive lines (108), with the associated substrate layers (107, 109) oriented as shown. Such positioning of the previously separate devices, as shown in FIG. 2A, to an vertically interfaced position such as that depicted in FIG. 2B may be termed “face-to-face” interfacing, or “vertical stacking”, or “bonding” of the two devices, as discussed above. The top bulk substrate layer (102) in the depicted embodiment is a thinned version of the top bulk substrate layer (101) depicted in FIG. 2A. Thinning may be accomplished before or after the substrate layers (107, 109) are bonded at the conductive line series (108) interface, using chemical mechanical polishing (“CMP”), grinding, or silicon wet etch processes, in the preferred silicon-based embodiment, to minimize the distance between the series of conductive lines (108) and the location of external contact portions, such as the external contact portion (140) depicted in FIG. 1. For example, the bulk silicon substrate layer (102) preferably is thinned to between about 10 microns and about 15 microns in thickness.

Subsequent to bonding, a dielectric plug (110) may be formed through the top bulk substrate layer (102), as depicted in FIG. 2C. The dielectric plug (110), preferably comprising silicon dioxide or other materials used to electronically isolate conductive layers in microelectronic processing, is positioned in alignment with a conductive line (111) with which a contact is to be interfaced, and is formed using conventional patterning, trenching, and deposition techniques. Referring to FIG. 2D, an etch stop dielectric layer (112) is formed adjacent the top bulk substrate layer (102) and dielectric plug (110) to isolate these layers from subsequent treatments used to form a conductive layer through the dielectric plug (110), and also to provide a relatively slow etch rate as compared with adjacent materials exposed to preferred etchants, to enable a controlled stoppage of etching during patterning and etching to form and isolate a contact, as described below. The etch stop dielectric layer (112) is selected in accordance with the etchants to be utilized on associated materials, as would be apparent to one skilled in the art, and preferably comprises a conventional etch stop material such as silicon nitride, which may be deposited using conventional techniques such as chemical or physical vapor deposition, at a thickness preferably between about 10 nanometers and about 200 nanometers.

Referring to FIG. 2E, a layer of photoresist (118) and a pattern (120) are positioned using conventional techniques to facilitate etching of a trench through the dielectric plug (110). As shown in FIG. 2F, an etch chemistry, preferably a substantially anisotropic etch chemistry such as a chlorine-based plasma to enable a trench (112) with substantially straight and parallel sidewalls, is introduced. The resulting trench (122) defines a pathway through which a layer of conductive material may form an electrical connection with the internal contact (111) adjacent the trench. Subsequent to creation of the trench (122), the pattern (120) and resist (118) layers are removed using conventional techniques to result in a structure such as that depicted in FIG. 2G. In a perpendicular view (not shown), the trench (122) preferably has a circular profile, but may also have a profile having a shape that is square, rectangular, or another shape. As shown in the cross-sectional view of FIG. 2G, the dielectric plug (110) preferably has a diameter sufficient to provide dielectric isolation around the entire portion of the trench (122) cutting through it. In the depicted embodiment, the profile of the dielectric plug (110) is about twice as wide as the trench (122). Thinner profiles for the dielectric plug (122) may be preferred in scenarios wherein several trenches are to be positioned adjacent each other, or wherein the material utilized for the dielectric plug (122) has a substantially low dielectric constant and very little material is needed to contribute to electrical isolation of the adjacent portion of the trench and subsequently-formed conductive layer. In another embodiment (not shown), the material comprising a barrier layer, such the barrier layer (114) depicted in FIG. 2H, may obviate the need for a dielectric plug by providing both barrier and electrically insulative properties.

Referring to FIG. 2H, a barrier layer (114) is deposited adjacent the exposed portions of the etch stop dielectric layer (112), dielectric plug (110), and conductive line (111). The slightly reduced trench (124) is substantially completely lined with the material comprising the barrier layer. The barrier layer (114) preferably comprises a material suited to isolate the selected conductive material from other adjacent structures. For example, in the case of copper, a preferred conductive material which may react adversely with adjacent dielectric materials and devices, a barrier layer (114) may be formed to block diffusion of copper or other conductive layer elements into adjacent layers of dielectric material. Preferable barrier layer (114) materials for copper conductive layers comprise refractory materials such as tantalum, tantalum nitride, titanium nitride, and tungsten or other materials that can inhibit diffusion from conductive layers into dielectric layers. Such barrier layers (114) preferably are between about 10 and 50 nanometers thick, and preferably are formed using a conformal CVD process. Known polymeric barrier layers may also be employed, subject to the requirement that they be selected from the subgroup of polymer barrier materials which have relatively good electromigration characteristics.

Referring to FIG. 2I, a layer of resist (126) and pattern (128) are positioned using conventional techniques to form an additional portion of the trench (130) depicted in FIG. 2J. The enlarged trench (130), preferably comprising two substantially rectangular profiles combined into a continuous “T” shape as in the depicted view, is subsequently filled with conductive material to form a conductive layer (132), as depicted in FIG. 2K, having the same shape. The conductive layer (132) may comprise metals such as copper, aluminum, tungsten, titanium, tin, indium, gold, nickel, palladium, and alloys thereof, formed using known techniques such as electroplating or chemical or physical vapor deposition. Alternatively, the conductive layer (132) may be made from doped polysilicon or a silicide, e.g., a suicide comprising tungsten, titanium, nickel, or cobalt, using known techniques. Preferably the conductive layer (132) comprises copper and is formed in a single deposition, such as a single electroplating treatment, to result in a continuous structure, as opposed to one which is formed by several discrete structures in contact with one another. For example, in reference to the conductive layer depicted in FIG. 2M, it is preferred that the external contact portion (140) and via portion (142) of the conductive layer (132) comprise one continuously deposited structure, as opposed to a structure comprising, for example, separate via and external contact portions which are subsequently interfaced or bonded together. The external contact portion (140) is dimensioned for conventional C4 contact utility using the patterning depicted in FIG. 2J. In one embodiment, for example, the external contact portion (140) may be between about 50 microns and about 150 microns wide, and between about 20 microns and about 100 microns in thickness as measured perpendicular to the substrate layer (107). The external contact portion (140) and via portion (142) preferably have substantially rectangular cross sectional profiles, as depicted in FIG. 2M, the external contact portion (140) generally being wider than the via portion (142) for C4 contact purposes. In one embodiment, for example, the via portion (142) is between about 15 microns and 50 microns wide, and the external contact portion (140) is between about 50 microns and 150 microns wide.

The pattern (128) and resist (126) of the depicted embodiment are removed using conventional techniques, resulting in a structure such as that depicted in FIG. 2L. A planarization treatment such as chemical mechanical polishing may be applied prior to removal of the resist and/or pattern to create a more uniform conductive layer (132) surface. Subsequent to removal of the resist layer (126), then exposed portions of the barrier layer (114) which are not disposed immediately between the conductive layer (132) and the substrate layer (107) may be removed using conventional etch back techniques, taking advantage of the previously formed etch stop dielectric layer (114) to prevent etching into the underlying bulk substrate layer (102), to result in a structure similar to that depicted in FIG. 2M, wherein the barrier layer (114) remains disposed between each region wherein the conductive layer (132) would otherwise come into contact with dielectric materials. The resultant structure comprises two substrates (107, 109) interfaced at a series of conductive lines (108) in contact with active areas or layers (106, 104) comprising the substrates (107, 109), one (111) of the internal conductive lines being in electrical contact with a conductive layer (132) extending from a position in the active layer (106) adjacent the internal conductive line (111) through and beyond the bulk substrate layer (102), the conductive layer (132) having a via portion (142) between the internal conductive line (111) and an external contact portion (140), the external contact portion comprising a C4 contact location.

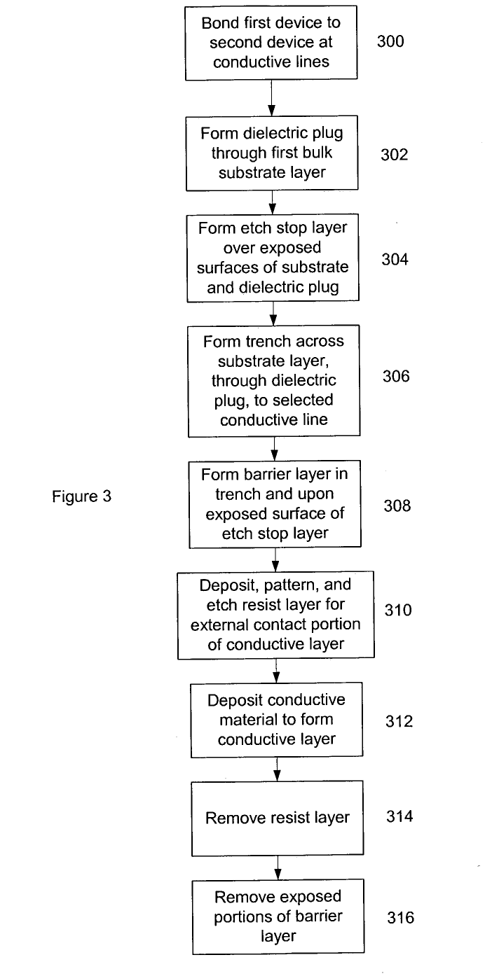

Referring to FIG. 3, a flowchart illustrating one embodiment of a process incorporating the aforementioned treatments is depicted. As described above, a first device is bonded or interfaced to a second device at conductive lines (300). Subsequently, a dielectric plug may be formed through the bulk substrate layer of the first substrate (302). An etch stop layer may then be formed over exposed surfaces of the dielectric plug and substrate (304), after which a trench may be formed across the substrate layer through the dielectric plug to facilitate an electrical connection with a selected conductive line (306). A barrier layer may then be formed in the trench and upon exposed surfaces of the etch stop layer (308), subsequent to which a resist layer may be deposited, patterned, and etched to facilitate formation of an external contact portion of a conductive layer (310). Conductive material may be formed into a conductive layer using the aforementioned trenches and patterning (312), after which the resist layer may be removed (314), and exposed portions of the barrier layer removed (316).

Thus, a novel contact solution is disclosed. Although the invention is described herein with reference to specific embodiments, many modifications therein will readily occur to those of ordinary skill in the art. Accordingly, all such variations and modifications are included within the intended scope of the invention as defined by the following claims.

1. A method to vertically interface wafer-based microelectronic devices comprising:
bonding a first device to a second device, each of the first and second devices comprising a substrate layer having an active layer adjacent a bulk substrate layer and a series of conductive lines coupled to the active layer, by interfacing the conductive lines of the first device with the conductive lines of the second device to provide an electrical connection between the active layer of the first device and the active layer of the second device;
forming a conductive layer across the bulk substrate layer and a portion of the active layer of the first device, the conductive layer having a via portion and an external contact portion, the external contact portion protruding beyond the bulk substrate layer of the first device, the via portion providing an electrical connection between the external contact portion and the one of the conductive lines of the first device.

2. The method of claim 1 wherein forming a conductive layer comprises a single deposition of conductive material.

3. The method of claim 2 wherein forming a conductive layer comprises a single electroplating.

4. The method of claim 1 wherein forming a conductive layer comprises forming a dielectric plug across the bulk substrate layer of the first device, and forming a trench across the dielectric plug, into which the via portion of the conductive layer is formed.

5. The method of claim 1 wherein forming a conductive layer comprises forming a trench across the bulk substrate layer and a portion of the active layer of the first device, and depositing a barrier layer into the trench and upon an exposed surface of the bulk substrate layer opposite the bulk substrate layer from the active layer, to isolate via and external contact portions of the subsequently formed conductive layer from the substrate layer.

6. The method of claim 4 further comprising forming an etch stop dielectric layer adjacent the bulk substrate layer and an exposed portion of the dielectric plug, subsequent to formation of the plug and before forming a trench across the dielectric plug.

7. The method of claim 1 further comprising thinning the bulk substrate layer of the first device before forming a conductive layer across the bulk substrate layer and a portion of the active layer of the first device.

8. The method of claim 1 wherein the conductive layer comprises a metal selected from the group comprising copper, aluminum, tungsten, titanium, tin, indium, gold, nickel, and palladium.

9. The method of claim 1 wherein the substrate layer comprises silicon.

10. The method of claim 4 wherein the dielectric plug comprises silicon dioxide.

11. The method of claim 7 wherein thinning the bulk substrate layer of the first device comprises removing portions of the bulk substrate layer until said bulk substrate layer has a thickness less than about 20 microns.

12. The method of claim 5 further comprising removing portions of the barrier layer not disposed immediately between the conductive layer and the substrate layer.

13. A method to provide external conductive access to an internal contact interface comprising:
forming a trench through a substrate layer of a first device to an internal contact of the first device, the internal contact being positioned between the substrate layer and an internal contact of a second device;
forming a conductive layer to fill the trench and extend beyond the substrate layer.

14. The method of claim 13 wherein forming a conductive layer comprises a single deposition of conductive material.

15. The method of claim 14 wherein forming a conductive layer comprises a single electroplating.

16. The method of claim 13 wherein forming a conductive layer comprises forming a dielectric plug across a portion of the substrate layer, and forming a trench through the dielectric plug to the internal contact of the first device, into which the conductive layer is formed.

17. The method of claim 13 further comprising forming a barrier layer between the conductive layer and the substrate layer.

18. The method of claim 13 further comprising thinning the substrate layer before forming the conductive layer.

19. The method of claim 13 wherein the conductive layer comprises a metal selected from the group comprising copper, aluminum, tungsten, titanium, tin, indium, gold, nickel, and palladium.

20. The method of claim 13 where the substrate layer comprises silicon.

21. The method of claim 16 wherein the dielectric plug comprises silicon dioxide.

22. The method of claim 18 wherein thinning the substrate layer comprises removing portions of the substrate layer until said substrate layer has a thickness less than about 20 microns.

23. A microelectronic structure comprising:
a first substrate layer comprising a first bulk substrate layer and a first active layer;
a second substrate layer comprising a second bulk substrate layer and a second active layer;
a series of internal contacts coupled between the first and second active layers;
a conductive layer extending from a position in the first active layer adjacent one of the series of internal contacts, through and beyond the first bulk substrate layer;
wherein the conductive layer comprises a continuous structure.

24. The microelectronic structure of claim 24 further comprising a barrier layer disposed between the conductive layer and the first substrate layer.

25. The microelectronic structure of claim 23 wherein a dielectric plug is positioned between the conductive layer and the first bulk substrate layer.

26. The microelectronic structure of claim 23 wherein the conductive layer comprises a via portion disposed within the first substrate layer, and an external contact portion positioned external to the first substrate layer, the via and external contact portions having substantially rectangular cross sections, each defined by a width dimension substantially parallel to the plane of the first substrate layer.

27. The microelectronic structure of claim 26 wherein the width of the external contact portion is greater than the width of the via portion.

28. The microelectronic structure of claim 27 wherein the width of the via portion is about 50 microns, and wherein the width of the external contact portion is about 150 microns.

29. The microelectronic structure of claim 23 wherein the first bulk substrate layer has a thickness less than about 15 microns.

30. The microelectronic structure of claim 23 wherein the conductive layer is formed by a single electroplating.

31. The microelectronic structure of claim 23 wherein the conductive layer comprises a metal selected from the group comprising copper, aluminum, tungsten, titanium, tin, indium, gold, nickel, and palladium.

32. The microelectronic structure of claim 23 wherein the first substrate layer comprises silicon.

33. The microelectronic structure of claim 25 wherein the dielectric plug comprises silicon dioxide.

34. The microelectronic structure of claim 24 wherein the barrier layer comprises a material selected from the group consisting of tantalum, tantalum nitride, titanium nitride, and tungsten.
